(19) United States
(12) Patent Application Publication
(10) Pub. No.: US 2015/0373828 A1
(43) Pub. Date: Dec. 24, 2015

(54) DISPLAY DEVICE

(71) Applicant: Samsung Display Co., Ltd., Yongin-City (KR)

(72) Inventors: Donghee YE, Daegu (KR); Minwook PARK, Asan-si (KR)

(21) Appl. No.: 14/609,156

(22) Filed: Jan. 29, 2015

(30) Foreign Application Priority Data
Jun. 24, 2014 (KR) 10-2014-0077622

(51) Int. Cl. H05K 1/02; G02F 1/1333; H05K 1/18; G02F 1/1337; G02F 1/1343; G02F 1/133; G02F 1/1368

(52) U.S. Cl. CPC H05K 1/028; G02F 1/13306; G02F 1/133305; G02F 1/1368; G02F 1/1337; G02F 1/134336; H05K 1/181; H05K 2201/10128

(57) ABSTRACT

A display device includes a display panel, a printed circuit board, and a flexible printed circuit board. The display panel includes a curved display surface for displaying an image. The curved display surface has a first curvature radius and includes a first display side and a second display side connected to the first display side. The printed circuit board is electrically connected to the display panel. The flexible printed circuit board overlaps with the first display side and connects the printed circuit board and the display panel. The display panel includes pixels arranged in a matrix comprising m rows and n columns, wherein the n columns are disposed substantially parallel to the first display side and the m rows are disposed substantially parallel to the second display side, and pixels arranged in an i-th row among the pixels display a same color.

### CROSS-REFERENCE TO RELATED APPLICATION

This U.S. non-provisional patent application claims priority under 35 U.S.C. §119 to Korean Patent Application No. 10-2014-0077622 filed Jun. 24, 2014, the contents of which are hereby incorporated by reference in their entirety.

### BACKGROUND

1. Technical Field

The present disclosure relates to a display device. More particularly, the present disclosure relates to a curved surface display device.

2. Description of the Related Art

A flat panel display device can be used in various types of information processing devices (for example, television sets, monitors, notebook computers, mobile phones, etc.) to display an image. In recent years, a curved surface display device having a curved shape has been developed. The curved surface display device includes a display area having a curved display surface which enhances the three-dimensional effect, sense of immersion (or immersiveness), and image presence to the viewer.

### SUMMARY

The inventive concept discloses a display device having improved image display quality.

According to some embodiments of the inventive concept, a display device includes a display panel, a printed circuit board, and a flexible printed circuit board. The display panel includes a curved display surface for displaying an image. The curved display surface has a first curvature radius and includes a first display side and a second display side connected to the first display side. The printed circuit board is electrically connected to the display panel. The flexible printed circuit board overlaps with the first display side and connects the printed circuit board and the display panel. The display panel includes a plurality of pixels arranged in a matrix comprising m rows and n columns, wherein the n columns are disposed substantially parallel to the first display side and the m rows are disposed substantially parallel to the second display side, and pixels arranged in an i-th row among the pixels display a same color. “n” and “m” are natural numbers and “i” is a natural number greater than zero and equal to or less than “m”.

In one embodiment, the second display side may have a straight profile.

In one embodiment, among the pixels arranged in a j-th column, the pixels disposed adjacent to each other may display different colors and “j” may be a natural number greater than zero and equal to or less than “n”.

In one embodiment, each of the pixels may include a first pixel side substantially parallel to the first display side and a second pixel side substantially parallel to the second display side, and a length of the first pixel side may be shorter than a length of the second pixel side.

In one embodiment, the curved display surface may further include a third display side connected to the second display side. The printed circuit board may further include a first printed circuit board and a second printed circuit board spaced apart from the first printed circuit board. The flexible printed circuit board may further include a first flexible printed circuit board overlapping with the first display side and connecting the first printed circuit board and the display panel, and a second flexible printed circuit board overlapping with the third display side and connecting the second printed circuit board and the display panel.

In one embodiment, at least one of the first flexible printed circuit board and the second flexible printed circuit board may be provided in plural.

In one embodiment, the display device may further include gate lines included in the display panel, and a gate driver electrically connected to the gate lines to apply a gate signal to the gate lines.

In one embodiment, the curved display surface may further include a display area for displaying the image and a non-display area in which the image is not displayed.

In one embodiment, the gate driver may be mounted on the display panel and overlap with the non-display area.

In one embodiment, the curved display surface may further include a fourth display side connected to the first display side and spaced apart from the second display side. The gate driver may further include a first gate driver and a second gate driver spaced apart from the first gate driver. The first gate driver may be disposed adjacent to the second display side, and the second gate driver may be disposed adjacent to the fourth display side.

In one embodiment, the gate driver may overlap with the first display side.

In one embodiment, each of the pixels may include a pixel thin film transistor, a pixel electrode electrically connected to the pixel thin film transistor, and a common electrode disposed facing the pixel electrode.

In one embodiment, the pixel electrode may include a trunk portion and a plurality of branch portions extending from the trunk portion.

In one embodiment, the pixels may be respectively disposed in pixel areas, and each of the pixel areas may further include a plurality of domains, and the domains may be separated from one another by the trunk portion.

In one embodiment, the branch portions may extend substantially parallel to each other within each domain and extend in different directions depending on the domains.

In one embodiment, the display panel may further include a first substrate, a second substrate facing the first substrate, and a liquid crystal layer interposed between the first and second substrates.

In one embodiment, the liquid crystal layer may include liquid crystal molecules having an alignment that changes in response to voltages applied to the pixel electrode and the common electrode, and the liquid crystal molecules may be aligned in different directions depending on the domains.

In one embodiment, the flexible printed circuit board may be provided in plural.

In one embodiment, the display panel may further include a plurality of unit display panels.

In one embodiment, the first curvature radius may range from about 3000 mm to about 5000 mm.

Accordingly, the display quality of the display device may be improved using one or more of the above embodiments.

### BRIEF DESCRIPTION OF THE DRAWINGS

The above and other advantages of the inventive concept will be readily apparent with reference to the following detailed description and drawings.

FIG. 1 is a perspective view showing a display device according to an exemplary embodiment.

FIG. 2 is a perspective view showing a display panel in the display device of FIG. 1.

FIG. 3 is a perspective view showing the display panel according to an exemplary embodiment.

FIG. 4 is a plan view of the display panel of FIG. 3.

FIG. 5 is a plan view showing a pixel in a display device according to an exemplary embodiment.

FIG. 6 is a cross-sectional view taken along line I-I′ in FIG. 5.

FIG. 7 is a perspective view showing a display device according to another exemplary embodiment.

FIG. 8 is a perspective view showing a display device according to another exemplary embodiment.

FIG. 9 is a perspective view showing a display device according to another exemplary embodiment.

FIG. 10 is a perspective view showing a display device according to another exemplary embodiment.

FIG. 11 is a perspective view showing a display device according to another exemplary embodiment.

### DETAILED DESCRIPTION

It will be understood that when an element or layer is referred to as being “on”, “connected to” or “coupled to” another element or layer, it can either be disposed directly on, connected or coupled to the other element or layer, or with one or more intervening elements or layers being present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms “first”, “second”, etc. may be used herein to describe various elements, components, regions, layers and/or sections, the elements, components, regions, layers and/or sections should not be limited by those terms. Those terms are only used to distinguish one element, component, region, layer or section from another region, layer or section. Thus, a first element, component, region, layer or section as described in the specification could be termed a second element, component, region, layer or section without departing from the teachings of the present disclosure.

Spatially relative terms, such as “beneath”, “below”, “lower”, “above”, “upper” and the like, may be used herein for ease of description to describe one element or feature's spatial relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments and is not intended to limit the inventive concept. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art, and should not be interpreted in an idealized or overly formal sense unless expressly so defined herein.

The inventive concept will be described in detail herein with reference to the accompanying drawings.

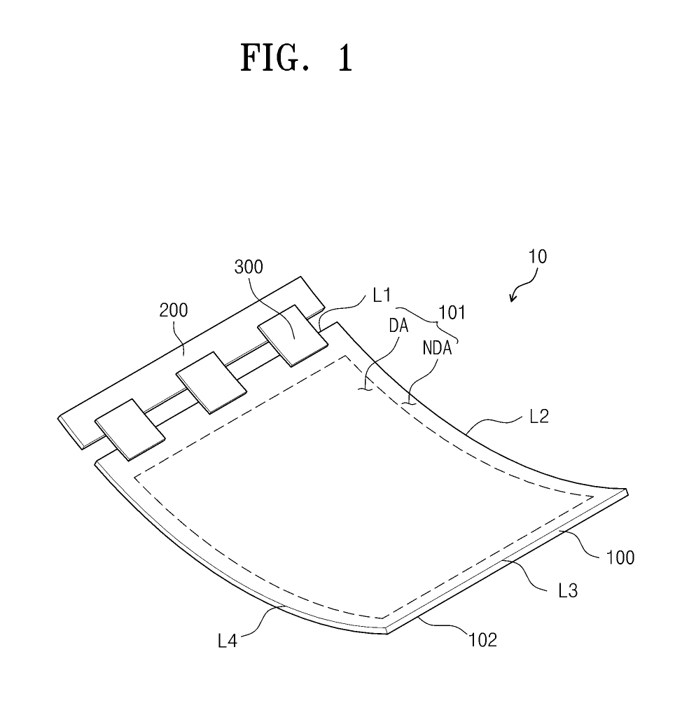

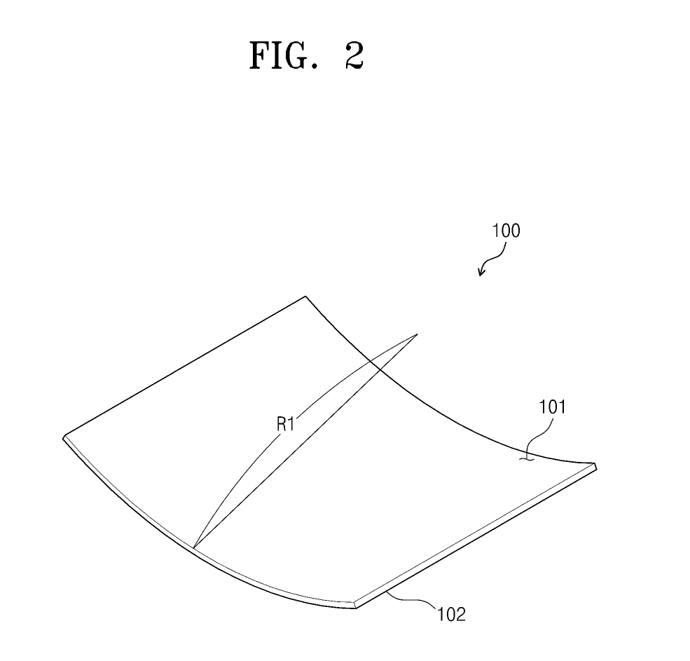

FIG. 1 is a perspective view showing a display device 10 according to an exemplary embodiment. FIG. 2 is a perspective view showing a display panel 100 included in the display device 10 of FIG. 1.

Referring to FIGS. 1 and 2, the display device 10 includes the display panel 100, a printed circuit board 200, and a flexible printed circuit board 300.

The display device 10 may include various display devices (e.g., an organic light emitting display device, a liquid crystal display device, a plasma display device, an electrophoretic display device, an electrowetting display device, etc.).

The printed circuit board 200 is electrically connected to the display panel 10. The flexible printed circuit board 300 is connected between the printed circuit board 200 and the display panel 100. The printed circuit board 200 and the flexible printed circuit board 300 will be described in further detail later in the specification.

Referring to FIG. 1, the display panel 100 is curved in a concave shape, but is not limited thereto.

The display panel 100 includes a curved display surface 101 and a rear surface 102 facing the curved display surface 101.

The curved display surface 101 may be, but is not limited to, a single curved surface with a radius of curvature. In the embodiment of FIG. 1, the curved display surface 101 has a first radius of curvature (herein referred to as a first radius curvature). However, it should be noted that the curved display surface 101 can have various curvature radii.

The curved display surface 101 includes a display area DA in which an image is displayed and a non-display area NDA in which no image is displayed. The non-display area NDA surrounds the display area DA. The display area DA has a substantially rectangular shape, but need not be limited to a rectangular shape.

The curved display surface 101 includes a first display side L1, a second display side L2, a third display side L3, and a fourth display side L4. The curved display surface 101 may have various shapes. In the present exemplary embodiment, the curved display surface 101 having a substantially rectangular shape when viewed in a plan view (in a direction as viewed from the curved display surface 101 to the rear surface 102) will be used as a representative example.

The first display side L1 has a substantially straight profile, and is connected between the second display side L2 and the fourth display side L4.

The second display side L2 is connected to the first display side L1 and has the first curvature radius R1. In the present exemplary embodiment, at least a portion of the second display side L2 is curved. The curved portion may correspond to a portion of a circle, a portion of an oval, a portion of a parabola, or a portion of a hyperbola. However, the shape of the curved portion need not be limited to a specific shape as long as the curved portion has the first curvature radius R1. The curved portion may have a single curvature radius or multiple curvature radii. When the curved portion has a single curvature radius, the curvature radius is constant.

When the curved portion of the second display side L2 corresponds to a portion of a circle, the first curvature radius R1 has a value corresponding to a radius of the circle. Since the curved display surface 101 includes the second display side L2, the curved display surface 101 also has the first curvature radius R1. However, when the display panel 100 is curved in a concave shape when viewed from the rear surface 102, the rear surface 102 may also have the first curvature radius R1.

The first curvature radius R1 may range from about 3000 mm to about 5000 mm. When the first curvature radius R1 is less than about 3000 mm, a viewer may have difficulty recognizing the image displayed on the display device 10. On the contrary, when the first curvature radius R1 is greater than about 5000 mm, the three-dimensional effect, sense of immersion (or immersiveness), and image presence on the display device 10 may deteriorate.

In the embodiment of FIGS. 1 and 2, the second display side L2 has a concave shape when viewed in the direction from the curved display surface 101 to the rear surface 102, but need not be limited thereto. For example, in some other embodiments, the second display side L2 may have a convex shape when viewed in the direction from the curved display surface 101 to the rear surface 102. In the embodiment of FIG. 1, the second display side L2 is longer than the first display side L1, but need not be limited thereto. For example, in some other embodiments, a length of the second display side L2 may be equal to or shorter than a length of the first display side L1.

The third display side L3 may have a substantially straight profile. The third display side L3 is connected to the second display side L2 and spaced apart from the first display side L1. In the present exemplary embodiment, the first and third display sides L1 and L3 are substantially parallel to each other. In some other embodiments, the first and third display sides L1 and L3 may not be parallel to each other.

The fourth display side L4 is connected between the first display side L1 and the third display side L3, and is spaced apart from the second display side L2. In the present exemplary embodiment, the second and fourth display sides L2 and L4 are substantially parallel to each other. In some other embodiments, the second and fourth display sides L2 and L4 may not be parallel to each other. The fourth display side L4 has the first curvature radius R1. For instance, at least a portion of the fourth display side L4 is curved. The curved portion may correspond to a portion of a circle, a portion of an oval, a portion of a parabola, or a portion of a hyperbola. However, the shape of the curved portion need not be limited to a specific shape as long as the curved portion has the first curvature radius R1. In addition, the curved portion may have a single curvature radius or multiple curvature radii.

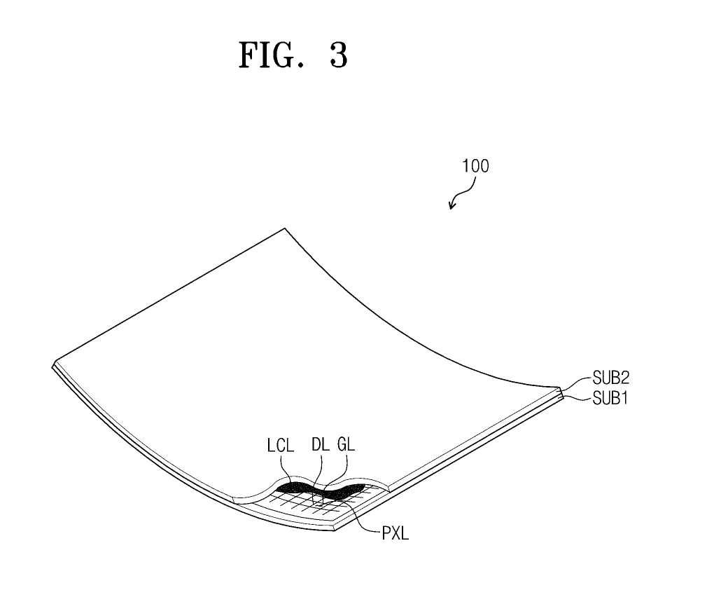

FIG. 3 is a perspective view showing the display panel according to an exemplary embodiment.

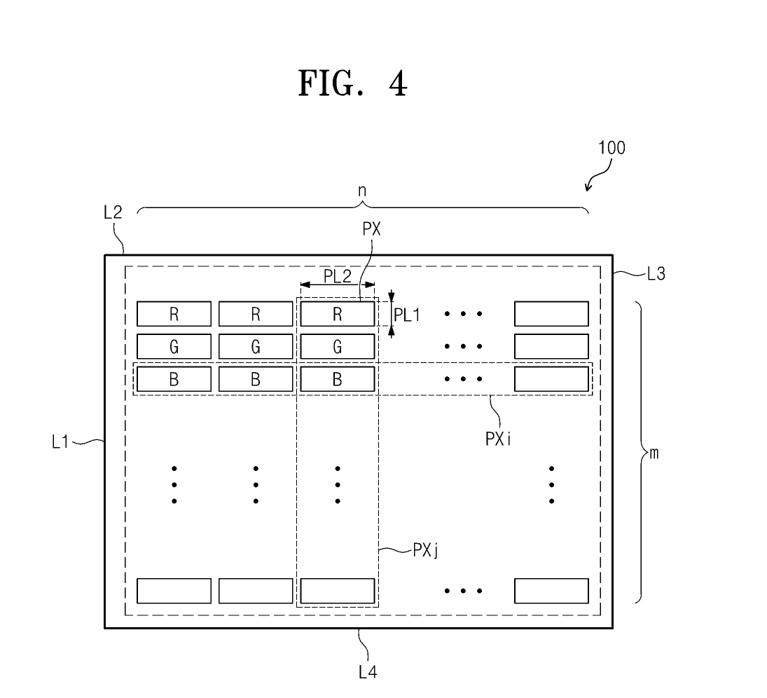

Referring to FIG. 3, the display panel 100 includes a first substrate SUB1, a second substrate SUB2 disposed facing the first substrate SUB1, and a liquid crystal layer LCL. The first substrate SUB1 includes a plurality of pixel areas PXL defined therein. For instance, the pixel areas PXL may be defined by gate lines GL and data lines DL. A plurality of pixels PX (refer to FIG. 4) are disposed in the respective pixel areas PXL.

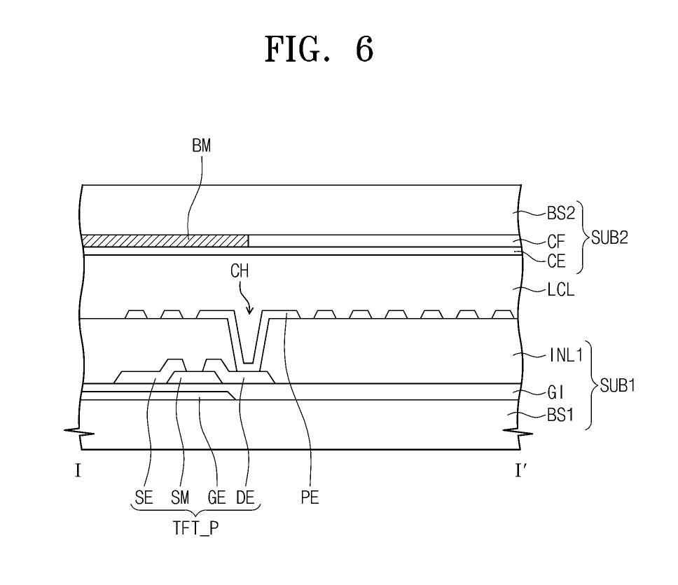

The liquid crystal layer LCL includes liquid crystal molecules having a dielectric anisotropy. The liquid crystal molecules of the liquid crystal layer LCL rotate in a specific direction between the first and second substrates SUB1 and SUB2 when an electric field is generated between a pixel electrode PE and a common electrode CE (refer to FIG. 6), thereby allowing transmittance of light passing through the liquid crystal layer LCL to be controlled.

FIG. 4 is a plan view of the display panel of FIG. 3.

Referring to FIG. 4, the display panel 100 includes the pixels PX. The pixels PX are disposed in the pixel areas PXL in a one-to-one correspondence. The pixels PX have the same structure and function. For instance, each pixel PX has a rectangular shape when viewed from the curved display surface 101 to the rear surface 102. However, the shape of the pixels PX need not be limited to a rectangular shape. For example, in some other embodiments, each pixel PX may have a circular shape, an oval shape, or a polygonal shape.

Each pixel PX includes a first pixel side that is substantially parallel to the first display side L1 and a second pixel side that is substantially parallel to the second display side L2. A length PL1 of the first pixel side is shorter than a length PL2 of the second pixel side, but need not be limited thereto. For example, in some other embodiments, the length PL1 of the first pixel side may be equal to or greater than the length PL2 of the second pixel side.

The pixels PX are arranged in a matrix comprising m rows by n columns. Each of “m” and “n” is a natural number.

When the first and third display sides L1 and L3 are substantially parallel to each other, the n columns may be substantially parallel to the first display side L1. When the first and third display sides L1 and L3 are not parallel to each other, all the n columns may be substantially parallel to the first display side L1 or the third display side L3. In addition, among the n columns, the columns disposed more adjacent and closer to the first display side L1 than the third display side L3 are substantially parallel to the first display side L1, and the columns disposed more adjacent and closer to the third display side L3 than the first display side L1 are substantially parallel to the third display side L3.

When the second and fourth display sides L2 and L4 are substantially parallel to each other, the m rows may be substantially parallel to the second display side L2. When the second and fourth display sides L2 and L4 are not parallel to each other, all the m rows may be substantially parallel to the second display side L2 or the fourth display side L4. In addition, among the m rows, the rows disposed more adjacent and closer to the second display side L2 than the fourth display side L4 are substantially parallel to the second display side L2, and the rows disposed more adjacent and closer to the fourth display side L4 than the second display side L2 are substantially parallel to the fourth display side L4.

Among the pixels PX, pixels PXi arranged in an i-th row may display the same color. In the present exemplary embodiment, “m” is a natural number, and “i” is a natural number greater than zero and equal to or less than “m”. In addition, pixels adjacent to each other among pixels PXj arranged in a j-th column may display different colors. In the present exemplary embodiment, “n” is a natural number, and “j” is a natural number greater than zero and equal to or less than “n”. The color may include at least one of red, green, blue, and white colors.

In more detail, the pixels arranged in the same row may display the same color. For instance, the pixels arranged in a first row may display red color, the pixels arranged in a second row may display green color, and the pixels arranged in a third row may display blue color, but need not be limited thereto. For example, the pixels arranged in the first row may display any one of green, blue, and white colors.

Among the pixels arranged in the same column, the pixels adjacent to each other may display different colors. For instance, among the pixels arranged in a first column, the pixel arranged in the first row and the first column may display red color; and the pixel that is arranged in the second row and the first column (and that is adjacent to the pixel arranged in the first row and the first column) may display green color. In addition, the pixel arranged in the second row and the first column may display green color; and the pixel that is arranged in the third row and the first column (and that is adjacent to the pixel arranged in the second row and the first column) may display blue color. That is, pixels adjacent to each other among the pixels arranged in the same column may display different colors. In the present exemplary embodiment, the pixel arranged in the first row and the first column may display red color as shown in FIG. 1, but need not be limited thereto. For instance, the pixel arranged in the first row and the first column may display any one of green, blue, and white colors.

In a conventional curved surface display device, when a first substrate (including thin film transistors) and a second substrate (including a black matrix) are misaligned and pixels arranged in the same row display different colors, a color mixture may occur between the pixels arranged in the same row. As a result, the display quality of the curved surface display device may deteriorate.

In contrast, in the display device according to the above-described embodiments, even though the pixels arranged in the same row display the same color, color mixture does not occur between the pixels when the first substrate SUB1 and the second substrate SUB2 (refer to FIG. 3) misalign. Accordingly, the display quality of the display device 10 is maintained even when misalignment of the substrates occurs.

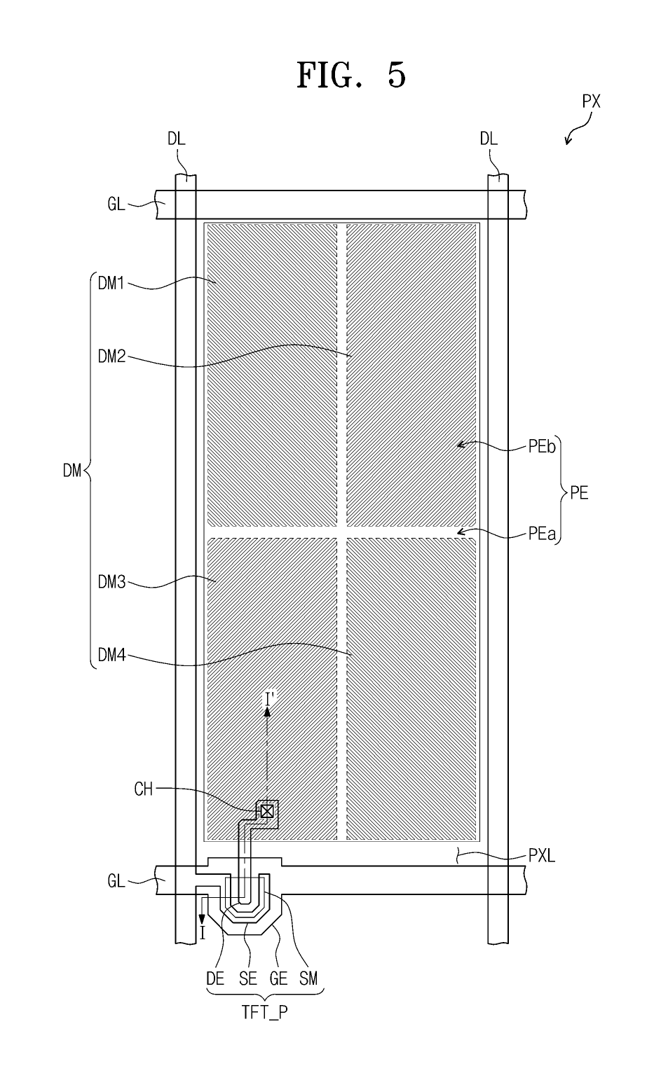

FIG. 5 is a plan view showing the pixel in the display device according to an exemplary embodiment. In the interest of clarity, FIG. 5 illustrates one pixel as a representative example since all the pixels have the same structure and function. FIG. 6 is a cross-sectional view taken along line I-I′ in FIG. 5.

Referring to FIGS. 5 and 6, the display panel 100 includes the first substrate SUB1, the second substrate SUB2, and the liquid crystal layer LCL.

The first substrate SUB1 includes a first base substrate BS1, the gate lines GL, and the data lines DL. The first substrate SUB1 has a curved shape.

The first base substrate BS1 is a transparent insulating substrate formed of silicon, glass, plastic, or other appropriate materials.

The gate lines GL are disposed on the first base substrate BS1. The gate lines GL are arranged substantially parallel to the second display side L2 (refer to FIG. 1).

The data lines DL are disposed on the first base substrate BS1. A gate insulating layer GI is disposed between the gate lines GL and the data lines DL. The data lines DL are arranged substantially parallel to the first display side L1 (refer to FIG. 1).

As described above, the pixel areas PXL are defined by the gate lines GL and the data lines DL, and include the pixels PX. Each pixel PX is connected to a corresponding gate line of the gate lines GL and a corresponding data line of the data lines DL.

Each pixel area PXL includes a plurality of domains DM. In addition, each pixel PX includes a pixel thin film transistor TFT_P, the pixel electrode PE electrically connected to the pixel thin film transistor TFT_P, and the common electrode CE facing the pixel electrode PE. The pixel thin film transistor TFT_P includes a gate electrode GE, a semiconductor pattern SM, a source electrode SE, and a drain electrode DE. The pixel thin film transistor TFT_P is configured to apply a data voltage to the pixel electrode PE.

The gate electrode GE is disposed on the first base substrate BS1. The gate electrode GE is disposed on a portion of the corresponding gate line of the gate lines GL. In some embodiments, the gate electrode GE may protrude from at least a portion of the corresponding gate line of the gate lines GL.

The gate electrode GE may include a metal material, such as nickel, chromium, molybdenum, aluminum, titanium, copper, tungsten, or an alloy thereof. The gate electrode GE may have a single-layer structure or a multi-layer structure. For example, in one embodiment, the gate electrode GE may have a triple-layer structure comprising sequentially stacked layers of molybdenum, aluminum, and molybdenum. In another embodiment, the gate electrode GE may have a double-layer structure comprising sequentially stacked layers of titanium and copper. In a further embodiment, the gate electrode GE may have a single-layer structure comprising an alloy of titanium and copper.

The gate insulating layer GI is disposed on the first base substrate BS1 covering the gate electrode GE. The gate insulating layer GI may be formed of an organic insulating material or an inorganic insulating material.

The semiconductor pattern SM is disposed on the gate insulating layer GI. The semiconductor pattern SM faces the gate electrode GE such that the gate insulating layer GI is disposed therebetween. The semiconductor pattern SM partially overlaps with the gate electrode GE.

The source electrode SE branches out from at least a portion of the corresponding data line of the data lines DL. At least a portion of the source electrode SE is disposed on the semiconductor pattern SM overlapping with the semiconductor pattern SM and the gate electrode GE.

The drain electrode DE is spaced apart from the source electrode SE, and the semiconductor pattern SM is partially disposed between the drain electrode DE and the source electrode SE. At least a portion of the drain electrode DE overlaps with the semiconductor pattern SM and the gate electrode GE.

Each of the source electrode SE and the drain electrode DE may include a metal material, such as nickel, chromium, molybdenum, aluminum, titanium, copper, tungsten, or an alloy thereof. Each of the source electrode SE and the drain electrode DE may have a single-layer structure or a multi-layer structure. For example, in one embodiment, each of the source electrode SE and the drain electrode DE may have a double-layer structure comprising sequentially stacked layers of titanium and copper. In another embodiment, each of the source electrode SE and the drain electrode DE may have a single-layer structure comprising an alloy of titanium and copper.

The first substrate SUB1 further includes a first insulating layer INL1 disposed on the gate insulating layer GI, the semiconductor pattern SM, the source electrode SE, and the drain electrode DE. The first insulating layer INL1 includes an insulating material (e.g., silicon oxide, silicon nitride, etc.).

A contact hole CH is formed through the first insulating layer INL1, so as to extend to and exposing at least a portion of the drain electrode DE.

The pixel electrode PE is disposed on the first insulating layer INL1, and is connected to the drain electrode DE through the contact hole CH.

The pixel electrode PE includes a transparent conductive material. In particular, the pixel electrode PE may include a transparent conductive oxide, such as indium tin oxide (ITO), indium zinc oxide (IZO), indium tin zinc oxide (ITZO), etc.

The pixel electrode PE includes a trunk portion PEa and a plurality of branch portions PEb. Each pixel area PXL includes the domains DM1, DM2, DM3, and DM4.

The domains DM1, DM2, DM3, and DM4 are separated from one another by the trunk portion PEa. The trunk portion PEa may be formed in various shapes. In the present exemplary embodiment, the trunk portion PEa has a cross shape as shown in FIG. 5. In the embodiment of FIG. 5, the domains include a first domain DM1, a second domain DM2, a third domain DM3, and a fourth domain DM4 separated from one another by the trunk portion PEa.

The branch portions PEb extend from the trunk portion PEa. Among the branch portions PEb, branch portions PEb adjacent to each other are spaced apart from each other. The distance between adjacent branch portions PEb is on the order of micrometers. In particular, the liquid crystal molecules of the liquid crystal layer LCL can be aligned in a specific azimuth on a surface that is substantially parallel to the base substrate.

The branch portions PEb extend in different directions according to the first to fourth domains DM1 to DM4. In addition, the branch portions PEb arranged in the same domain among the first to fourth domains DM1 to DM4 may extend substantially parallel to one another.

The second substrate SUB2 includes a second base substrate BS2, a color filter CF, the black matrix BM, and the common electrode CF. The second substrate SUB2 has a curved shape.

The second base substrate BS2 is a transparent insulating substrate formed of silicon, glass, plastic, or other appropriate materials.

The color filter CF is disposed on the second base substrate BS2 and determines the color of the light exiting from the pixels PX. The light is provided from a backlight unit (not shown). The backlight unit may have the same shape as the display panel 100 (e.g., a curved shape). Although not shown in figures, the backlight unit may include a light guide plate, a light source, and an optical sheet. The light guide plate guides the light provided from the light source to the display panel 100. The light source supplies the light to the light guide plate. The light source is disposed corresponding to a side surface of the light guide plate, but need not be limited thereto. For example, in some other embodiments, the light source may be disposed under the light guide plate. The light source may be provided as a plurality of light sources. The light source may include a light emitting diode or a cold cathode fluorescent lamp.

In the present exemplary embodiment, the color filter CF is included in the second substrate SUB2, but need not be limited thereto. For example, in some other embodiments, the color filter CF may be included in the first substrate SUB1 instead of the second substrate SUB2.

The color filter CF may be a red color filter, a green color filter, or a blue color filter. The color filter CF is disposed corresponding to each pixel area. The color filter CF may further include a white color filter.

The color filter CF is formed by forming a color filter layer (that can display red, green, blue, or other colors on the second base substrate BS2) and patterning the color filter layer using a photolithography process. In some other embodiments, the color filter CF may be formed by an inkjet method.

The black matrix BM is disposed on the second base substrate BS2 and overlaps with a light blocking area of the first substrate SUB1. The light blocking area corresponds to areas in which the gate lines GL, the data lines DL, and the pixel thin film transistor TFT_P are formed. Since the pixel electrode PE is not formed in the light blocking area, the liquid crystal molecules are not aligned in the light blocking area, and thus light leakage may occur. Accordingly, the black matrix BM is disposed in the light blocking area to prevent light from leaking. The black matrix BM may be formed at the same time as the color filter CF. In some other embodiments, the black matrix BM may be formed either before or after forming the color filter CF. The black matrix BM may be formed by forming a light blocking layer that absorbs light and patterning the light blocking layer using a photolithography process. In some other embodiments, the black matrix BM may be formed by an inkjet method. In the present exemplary embodiment, the color filter CF and the black matrix BM have the same thickness as shown in FIG. 6, but need not be limited thereto. In other embodiments, the color filter CF and the black matrix BM may have different thicknesses.

Although not shown in the figures, a planarization layer may be disposed on the black matrix BM and the color filter CF. The planarization layer serves to planarize the second substrate SUB2. The planarization layer may be formed of an organic insulating layer or an inorganic insulating layer.

The common electrode CE is disposed on the color filter CF and the black matrix BM. The common electrode CE receives a common voltage. The common electrode CE faces the pixel electrode PE and forms an electric field with the pixel electrode PE. As previously described, the electric field is used to drive the liquid crystal molecules of the liquid crystal layer LCL. In the present exemplary embodiment, the common electrode CE is disposed on the second substrate SUB2, but need not be limited thereto. For example, in some other embodiments, the common electrode CE may be disposed on the first substrate SUB1 instead of the second substrate SUB2.

The common electrode CE includes the transparent conductive material. For example, the common electrode CE may include a conductive metal oxide such as indium tin oxide (ITO), indium zinc oxide (IZO), indium tin zinc oxide (ITZO), etc.

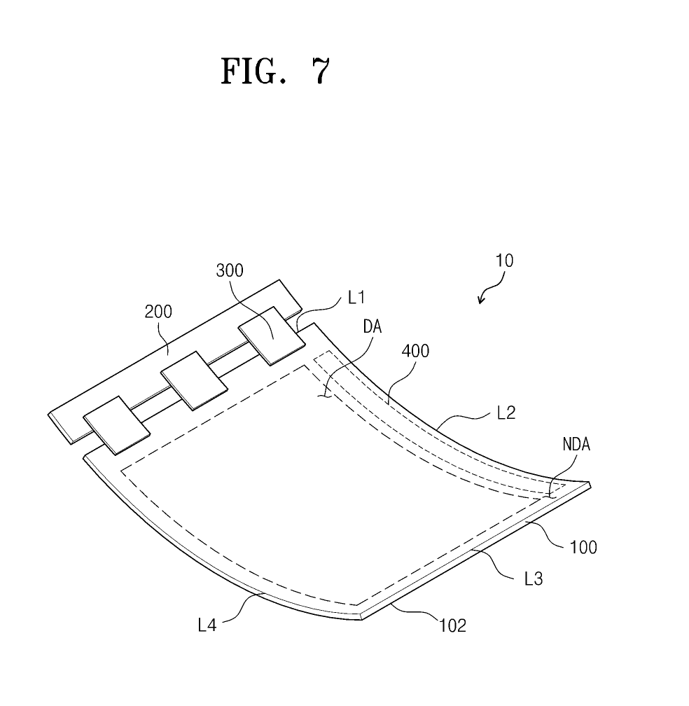

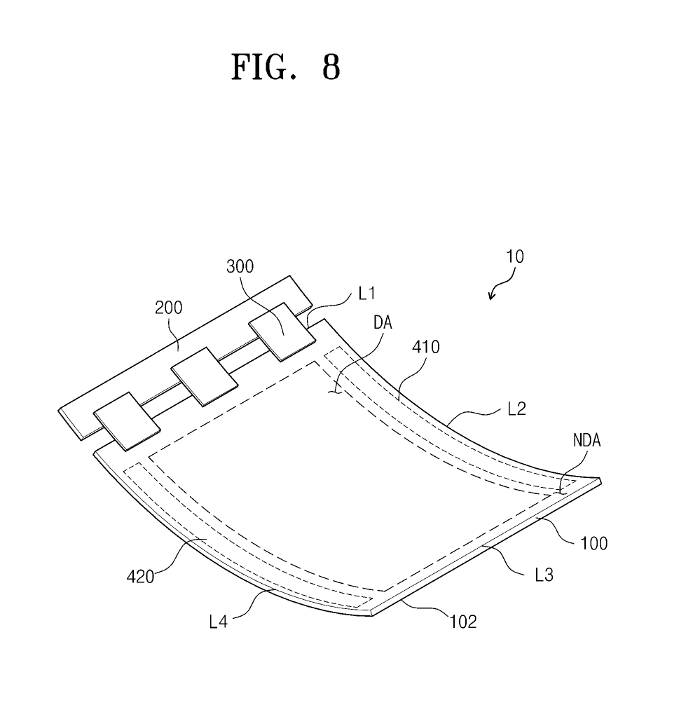

FIG. 7 is a perspective view showing a display device according to another exemplary embodiment, and FIG. 8 is a perspective view showing a display device according to another exemplary embodiment.

Referring to FIGS. 7 and 8, the display device 10 further includes a gate driver 400. The gate driver 400 is configured to apply gate signals to the gate lines GL (refer to FIG. 3). In FIG. 7, the gate driver 400 has a rectangular shape, but the shape of the gate driver 400 need not be limited to a rectangular shape. In some other embodiments, the gate driver 400 may have a circular shape, an oval shape, or a polygonal shape.

The gate driver 400 is electrically connected to at least one of the gate lines GL (refer to FIG. 3). The gate driver 400 is configured to receive an external signal from an external source (not shown) and apply the external signal to the gate lines GL (refer to FIG. 3). Alternatively, the gate driver 400 may generate a signal based on the external signal and apply the signal to the gate lines GL. The external signal may include an image signal, various control signals, or a driving voltage.

The gate driver 400 is disposed on the display panel 100. For instance, the gate driver 400 is mounted on the display panel 100. In FIGS. 7 and 8, the gate driver 400 is included in the display panel 100. In some other embodiments, the gate driver 400 may be included in the printed circuit board 200 or the flexible printed circuit board 300.

The gate driver 400 overlaps with the non-display area NDA. In FIGS. 7 and 8, the gate driver 400 overlaps with the non-display area NDA, but need not be limited thereto. For example, in some other embodiments, the gate driver 400 may overlap with the display area DA. In the display device 10 according to the present exemplary embodiment, a bezel area may be reduced since the gate driver 400 is included in the display panel 100.

Although not shown in the figures, the gate driver 400 may include an active device (e.g., a driving thin film transistor or a driving diode) or a passive device (e.g., a capacitor).

The driving thin film transistor may be fabricated at the same time as the pixel thin film transistor TFT_P. For instance, each of the driving thin film transistor and the pixel thin film transistor TFT_P may include portions that are formed by patterning one or more layers. Specifically, the driving thin film transistor and the pixel thin film transistor TFT_P may be fabricated from one or more conductive layers.

The gate driver 400 is disposed adjacent and substantially parallel to the second display side L2. The flexible printed circuit board 300 connects the printed circuit board 200 and the display panel 100, and the gate driver 400 is spaced apart from the flexible printed circuit board 300. In some other embodiments, the gate driver 400 may be disposed adjacent to the fourth display side L4.

The gate driver 400 may include a single gate driver or a plurality of gate drivers. Referring to FIG. 7, the display device 10 includes one gate driver 400. Referring to FIG. 8, the display device 10 may include two gate drivers (a first gate driver 410 and a second gate driver 420) but need not be limited to only two gate drivers.

Referring to FIG. 8, the first gate driver 410 is disposed adjacent and substantially parallel to the second display side L2. The second gate driver 420 is disposed adjacent and substantially parallel to the fourth display side L4. The first gate driver 410 may have a similar shape and size as the second gate driver 420. In some other embodiments, the first gate driver 410 and the second gate driver 420 may have different shapes and sizes.

The display device 10 according to the present exemplary embodiment may further include a data driver (not shown). The data driver is electrically connected to the data lines DL (refer to FIG. 3). The data driver is configured to apply data signals to the data lines DL.

The data driver is disposed on at least one of the printed circuit board 200 and the flexible printed circuit board 300.

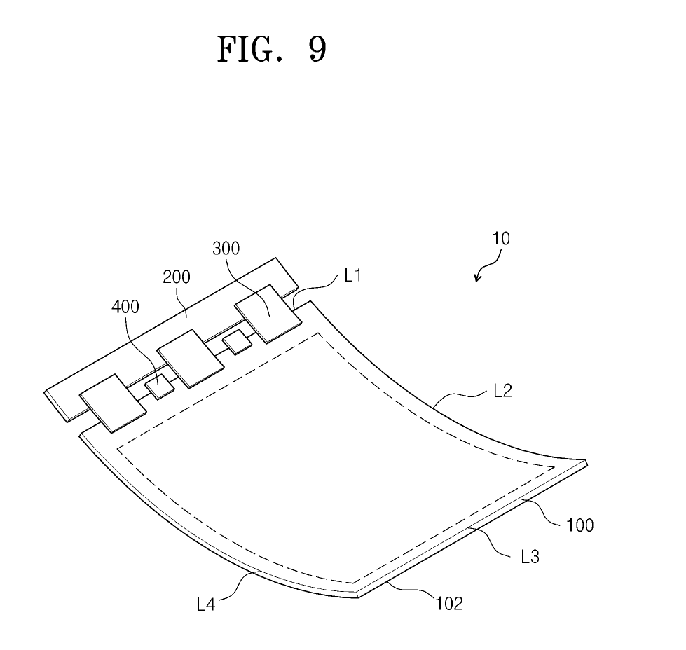

FIG. 9 is a perspective view showing a display device according to another exemplary embodiment. In FIG. 9, the same reference numerals denote the same elements as in FIGS. 7 and 8, and thus a detailed description of the same elements will be omitted.

Referring to FIG. 9, a gate driver 400 partially overlaps with the first display side L1. However, the gate driver 400 does not overlap with the second and fourth display sides L2 and L4.

The gate driver 400 is electrically connected to the gate lines GL (refer to FIG. 3). The gate driver 400 is connected to the gate lines GL by gate fan-out lines (not shown). The gate fan-out lines (not shown) extend to the second display side L2 from the gate driver 400 along the first display side L1 and are connected to the gate lines GL.

The gate driver 400 receives a gate control signal from a data driver (not shown). The gate driver 400 generates a gate signal in response to the gate control signal and applies the gate signal to the gate lines GL.

The gate driver 400 may include a plurality of gate drivers. The gate drivers 400 may be alternately arranged on the flexible printed circuit board 300 or disposed adjacent to one another. The gate drivers 400 have the same shape and size. In some other embodiments, the gate drivers 400 may have different shapes and sizes.

In FIG. 9, the gate driver 400 partially overlaps with the first display side L1, but need not be limited thereto. According to some other embodiments, the gate driver 400 may be disposed partially overlapping with the third display side L3.

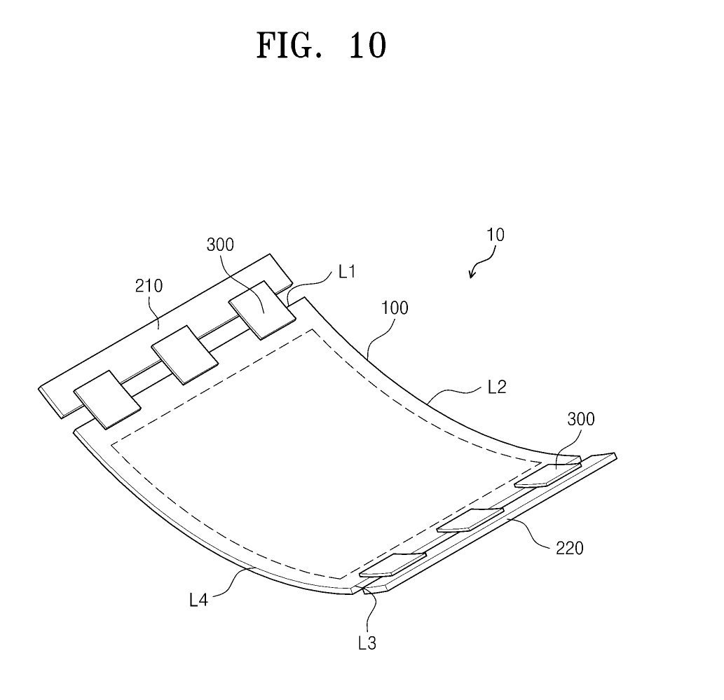

FIG. 10 is a perspective view showing a display device according to another exemplary embodiment.

Referring to FIGS. 7 to 10, the printed circuit board 200 is electrically connected to the display panel 100. The printed circuit board 200 is configured to drive the display panel 100. The printed circuit board 200 may include a driving substrate and a plurality of circuit parts mounted on the driving substrate. The printed circuit board 200 is disposed adjacent to the first display side L1. The printed circuit board 200 is disposed on a side surface of the display panel 100. In some other embodiments, if the printed circuit board 200 is elastic, the printed circuit board 200 may be disposed on the rear surface 102 of the display panel 100.

Referring to FIG. 10, the printed circuit board 200 includes a plurality of printed circuit boards. For instance, the printed circuit board 200 may include a first printed circuit board 210 and a second printed circuit board 220. The first printed circuit board 210 is disposed adjacent to the first display side L1 and connected to the display panel 100 by the flexible printed circuit board 300. The second printed circuit board 220 is disposed adjacent to the third display side L3 and connected to the display panel 100 by the flexible printed circuit board 300.

Referring to FIGS. 7 to 10, the flexible printed circuit board 300 connects the printed circuit board 200 and the display panel 300. The flexible printed circuit board 300 includes a base film (not shown) and an integrated circuit chip (not shown) mounted on the base film.

FIGS. 7 to 10 illustrate three flexible printed circuit boards 300, but the number of flexible printed circuit boards 300 need not be limited to three. For example, in some other embodiments, the flexible printed circuit board 300 may include one or more flexible printed circuit boards.

The flexible printed circuit board 300 overlaps with at least the first display side L1, but does not overlap with the second display side L2 and the fourth display side L4.

As previously mentioned, each of the second and fourth display sides L2 and L4 partially has a curved shape. In the display device 10 according to the present exemplary embodiment, the flexible printed circuit board 300 does not overlap with the second and fourth display sides L2 and L4, and thus the stress exerted onto the printed circuit board 200 and the flexible printed circuit board 300 can be reduced. Accordingly, the circuit parts in the printed circuit board 200 and the flexible printed circuit board 300 have a lower risk of damage, and as such the reliability of the display device 10 is improved. Therefore, the display quality of the curved surface display device 10 is maintained and does not degrade as quickly compared to a conventional curved surface display device.

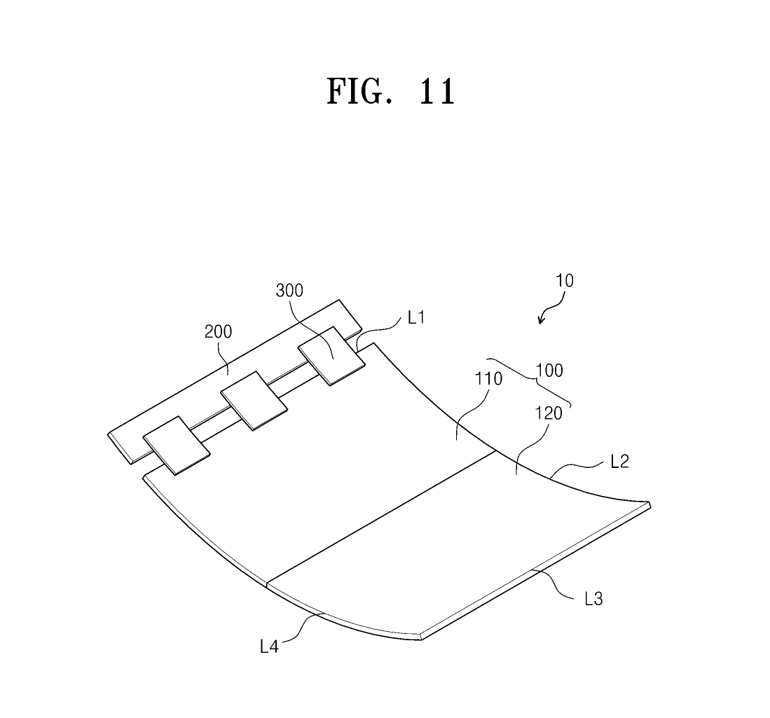

FIG. 11 is a perspective view showing a display device according to another exemplary embodiment.

Referring to FIG. 11, the display panel 100 may include a plurality of unit display panels. Although FIG. 11 illustrates two unit display panels, the number of unit display panels may be three or more in other embodiments. The display panel 100 includes a first unit display panel 110 and a second unit display panel 120 disposed adjacent to the first unit display panel 110. The first and second unit display panels 110 and 120 may share the second and fourth display sides L2 and L4, but need not be limited thereto. Although not shown in FIG. 11, the first and second unit display panels 110 and 120 may share the first and third display sides L1 and L3 along a direction in which the first and second unit display panels 110 and 120 are arranged. The first unit display panel 110 may have the same shape and size as the second unit display panel 120. In some other embodiments, the first unit display panel 110 and the second unit display panel 120 may have different shapes and sizes.

At least a portion of the unit display panels overlaps with the flexible printed circuit board 300. As shown in FIG. 11, the first unit display panel 110 overlaps with the flexible printed circuit board 300 and is connected to the printed circuit board 200 by the flexible printed circuit board 300. FIG. 11 illustrates three flexible printed circuit boards 300, but the number of the flexible printed circuit boards 300 need not be limited to three. For example, in some other embodiments, the flexible printed circuit board 300 may include one or more flexible printed circuit boards. The flexible printed circuit board 300 overlaps with the first display side L1 and does not overlap with the second display side L2 and the fourth display side L4. At least a portion of the second display side L2 is curved and the first display side L1 may have a substantially straight profile.

Although not shown in FIG. 11, the second unit display panel 120 may overlap with the flexible printed circuit board 300 and is connected to the printed circuit board 200 by the flexible printed circuit board 300. The flexible printed circuit board 300 overlaps with the third display side L3 and does not overlap with the second and fourth display sides L2 and L4. At least a portion of the second display side L2 is curved and the third display side L3 may have a substantially straight profile.

Although different exemplary embodiments of the inventive concept have been described, it is understood that the inventive concept is not be limited to the above-described embodiments, but that various changes and modifications can be made by one of ordinary skill in the art within the spirit and scope of the inventive concept as claimed herein.

What is claimed is:

1. A display device comprising:
a display panel including a curved display surface for displaying an image, the curved display surface having a first curvature radius and including a first display side and a second display side connected to the first display side;
a printed circuit board electrically connected to the display panel; and
a flexible printed circuit board overlapping with the first display side and connecting the printed circuit board and the display panel, the display panel comprising a plurality of pixels arranged in a matrix comprising m rows and n columns, wherein the n columns are disposed substantially parallel to the first display side and the m rows are disposed substantially parallel to the second display side, wherein pixels arranged in an i-th row among the pixels display a same color, and wherein “n” and “m” are natural numbers and “i” is a natural number greater than zero and equal to or less than “m”.

2. The display device of claim 1, wherein the second display side has a straight profile.

3. The display device of claim 1, wherein, among the pixels arranged in a j-th column, the pixels disposed adjacent to each other display different colors and “j” is a natural number greater than zero and equal to or less than “n”.

4. The display device of claim 1, wherein each of the pixels comprises:
a first pixel side substantially parallel to the first display side; and
a second pixel side substantially parallel to the second display side, and a length of the first pixel side is shorter than a length of the second pixel side.

5. The display device of claim 1, wherein the curved display surface further comprises a third display side connected to the second display side;
the printed circuit board further comprises a first printed circuit board and a second printed circuit board spaced apart from the first printed circuit board; and
the flexible printed circuit board further comprises:
a first flexible printed circuit board overlapping with the first display side and connecting the first printed circuit board and the display panel, and
a second flexible printed circuit board overlapping with the third display side and connecting the second printed circuit board and the display panel.

6. The display device of claim 5, wherein at least one of the first flexible printed circuit board and the second flexible printed circuit board is provided in plural.

7. The display device of claim 1, further comprising:
gate lines included in the display panel; and
a gate driver electrically connected to the gate lines to apply a gate signal to the gate lines.

8. The display device of claim 7, wherein the curved display surface further comprises:
a display area for displaying the image; and
a non-display area in which the image is not displayed.

9. The display device of claim 8, wherein the gate driver is mounted on the display panel and overlaps with the non-display area.

10. The display device of claim 9, wherein the curved display surface further comprises a fourth display side connected to the first display side and spaced apart from the second display side; and
the gate driver further comprises a first gate driver and a second gate driver spaced apart from the first gate driver, wherein the first gate driver is disposed adjacent to the second display side, and the second gate driver is disposed adjacent to the fourth display side.

11. The display device of claim 7, wherein the gate driver overlaps with the first display side.

12. The display device of claim 1, wherein each of the pixels comprises:
a pixel thin film transistor;
a pixel electrode electrically connected to the pixel thin film transistor; and
a common electrode disposed facing the pixel electrode.

13. The display device of claim 12, wherein the pixel electrode comprises:
a trunk portion; and
a plurality of branch portions extending from the trunk portion.

14. The display device of claim 13, wherein the pixels are respectively disposed in pixel areas, and each of the pixel areas further comprises a plurality of domains, and the domains are separated from one another by the trunk portion.

15. The display device of claim 14, wherein the branch portions extend substantially parallel to each other within each domain and extend in different directions depending on the domains.

16. The display device of claim 12, wherein the display panel further comprises:
a first substrate;
a second substrate facing the first substrate; and
a liquid crystal layer interposed between the first and second substrates.

17. The display device of claim 16, wherein the liquid crystal layer comprises liquid crystal molecules having an alignment that changes in response to voltages applied to the pixel electrode and the common electrode, and wherein the liquid crystal molecules are aligned in different directions depending on the domains.

18. The display device of claim 1, wherein the flexible printed circuit board is provided in plural.

19. The display device of claim 1, wherein the display panel further comprises a plurality of unit display panels.

20. The display device of claim 1, wherein the first curvature radius ranges from about 3000 mm to about 5000 mm.
